(19) United States
(12) Patent Application Publication
(10) Pub. No.: US 2018/0331230 A1
(43) Pub. Date: Nov. 15, 2018

(54) SEMICONDUCTOR DEVICE AND ELECTRONIC APPARATUS

(71) Applicant: SEIKO EPSON CORPORATION, Tokyo (JP)

(72) Inventor: Manabu KUDO, Suwa-shi (JP)

(73) Assignee: SEIKO EPSON CORPORATION, Tokyo (JP)

(21) Appl. No.: 15/968,218

(22) Filed: May 1, 2018

(30) Foreign Application Priority Data
May 11, 2017 (JP) 2017-094469

(51) Int. Cl. H01L 29/786; H01L 27/12; H01L 29/40; H01L 29/423; H01L 29/49; H01L 21/02; H01L 21/265; H01L 29/66; H01L 23/00; G02F 1/167; G02F 1/1333; G02F 1/1368; G02F 1/1362

(52) U.S. Cl. CPC H01L 29/78603; G02F 2202/104; H01L 27/1218; H01L 27/1262; H01L 27/1274; H01L 29/408; H01L 29/42384; H01L 29/4908; H01L 29/78675; H01L 21/02488; H01L 21/02592; H01L 21/02532; H01L 21/0262; H01L 21/02675; H01L 21/26513; H01L 29/66757; H01L 23/562; G02F 1/167; G02F 1/133377; G02F 1/1368; G02F 1/136227; G02F 2001/133357; G02F 2001/133302; G02F 2201/121; H01L 27/1222

(57) ABSTRACT

A semiconductor device includes a substrate, a thin film transistor, and an insulating film that is provided between the substrate and the thin film transistor, in which the insulating film includes a first silicon oxide film, a silicon nitride film that is formed on the first silicon oxide film, and a second silicon oxide film that is formed on the silicon nitride film, and the nitrogen concentration in the first silicon oxide film is lower than that in the second silicon oxide film.

### BACKGROUND

### 1. Technical Field

The present invention relates to a semiconductor device and an electronic apparatus.

### 2. Related Art

A switching element for controlling image display is disposed in a display device such as a liquid crystal display device, an organic EL display device, or an electronic paper. As the switching element, a thin film transistor (TFT) is widely used in a semiconductor device. A structure of the TFT is disclosed in JP-A-2017-11111. According to JP-A-2017-11111, a lower insulating film is provided on a substrate, and a semiconductor layer is provided on the lower insulating film. In the semiconductor layer, each of a source region, a channel region, and a drain region is provided.

Further, a gate insulating film is provided on the semiconductor layer, and the lower insulating film and the gate insulating film limit regions where ions flow. A gate electrode is provided on the gate insulating film. The gate electrode is provided in a portion opposite to the channel region. After the gate electrode is patterned and masked, ions are implanted into the semiconductor layer. At this time, it is necessary that the gate electrode has a thickness of 250 nm or more. Further, an upper insulating film is provided on the gate electrode.

It is preferable that the gate electrode is formed of a metal having a low resistance and a high melting point. Due to the low resistance, responsiveness of the switching element can be improved. In addition, due to the high melting point, a high-temperature process can be performed. However, since the metal having a high melting point has high specific resistance, the thickness of the gate electrode is thick in order to allow the gate electrode to have low resistance. During formation of the metal film, a tensile stress is generated from the metal film. In a case where the thickness of the gate electrode is large, the substrate warps. Therefore, there may be a case where a vacuum chuck for holding the substrate cannot adsorb the substrate. Therefore, it is desirable that the warpage of the substrate is suppressed even in a case where the metal film such as the gate electrode is provided.

### SUMMARY

An advantage of some aspects of the invention is to solve the problem described above, and the invention can be implemented as the following forms or application examples.

### Application Example 1

A semiconductor device according to this application example includes: a substrate; a thin film transistor; and an insulating film that is provided between the substrate and the thin film transistor, in which the insulating film includes a first silicon oxide film, a silicon nitride film that is formed on the first silicon oxide film, and a second silicon oxide film that is formed on the silicon nitride film, and a nitrogen concentration in the first silicon oxide film is lower than a nitrogen concentration in the second silicon oxide film.

According to this application example, the semiconductor device includes the substrate and the thin film transistor. The insulating film is disposed between the substrate and the thin film transistor. The insulating film suppresses the flow of unnecessary ions that change the characteristics of the thin film transistor. In the insulating film, the first silicon oxide film, the silicon nitride film, and the second silicon oxide film are disposed in this order.

The second silicon oxide film is positioned close to the thin film transistor and has a high nitrogen concentration. The silicon oxide film having a high nitrogen concentration has a low trap level, and thus accumulation of + charges is suppressed. Deterioration in the performance of the thin film transistor can be suppressed.

The silicon nitride film has a high blocking effect against impurity ions. Therefore, a variation in the characteristics of the thin film transistor caused by impurity ions can be suppressed. The first silicon oxide film has a low nitrogen concentration. The silicon oxide film having a low nitrogen concentration can increase the compressive stress. Accordingly, even in a case where the film used in the thin film transistor has a tensile stress, the stress can be well-balanced by the first silicon oxide film. As a result, the warpage of the semiconductor device can be suppressed.

### Application Example 2

In the semiconductor device according to the application example, the nitrogen concentration in the first silicon oxide film is 3E²⁰ atoms/CC to 9E²⁰ atoms/CC.

According to this application example, the nitrogen concentration in the first silicon oxide film is 3E²⁰ atoms/CC to 9E²⁰ atoms/CC. At this time, the stress of the first silicon oxide film can be made to be a compressive stress and can be made to be 280 MPa to 480 MPa.

### Application Example 3

In the semiconductor device according to the application example, a gate electrode of the thin film transistor includes molybdenum.

According to this application example, the gate electrode in the thin film transistor includes molybdenum. Molybdenum is a metal having a high melting point. Accordingly, a manufacturing process including a high-temperature process can be adopted. The electrical specific resistance of molybdenum is about twice that of aluminum, but the resistance can be reduced by increasing the thickness of the film formed of molybdenum. In a case where the thickness of the film formed of molybdenum increases, a tensile stress is likely to be generated. Even in a case where the film formed of molybdenum is provided in the substrate, the stress can be well-balanced by the first silicon oxide film. Therefore, the warpage of the substrate can be suppressed.

### Application Example 4

An electronic apparatus according to this application example includes the above-described semiconductor device.

According to this application example, the electronic apparatus includes the above-described semiconductor device. In the above-described semiconductor device, the warpage of the substrate is suppressed. Accordingly, in the electronic apparatus, the warpage of the semiconductor device can be suppressed.

### Application Example 5

A method of manufacturing a semiconductor device according to this application example includes: forming a first silicon oxide film using silane gas and nitrogen oxide gas; forming a silicon nitride film; and forming a second silicon oxide film using silane gas and nitrogen oxide gas, in which in the forming of the first silicon oxide film, a ratio of a concentration of the silane gas to a concentration of the nitrogen oxide gas is lower than that in the forming of the second silicon oxide film.

According to this application example, the method of manufacturing a semiconductor device includes: forming the first silicon oxide film, forming the silicon nitride film; and forming the second silicon oxide film. In the forming of the first silicon oxide film and the forming of the second silicon oxide film, silane gas and nitrogen oxide gas are used.

In the forming of the first silicon oxide film, the ratio of the concentration of the silane gas to the concentration of the nitrogen oxide gas is lower than that in the forming of the second silicon oxide film. This way, by controlling the ratio of the concentration of the silane gas to the concentration of the nitrogen oxide gas, the semiconductor device in which the nitrogen concentration in the first silicon oxide film is lower than that of the second silicon oxide film can be manufactured.

The silicon oxide film having a low nitrogen concentration can increase the compressive stress. Accordingly, even in a case where the metal film having a high tensile stress is provided in the substrate in a post step, the warpage of the substrate can be suppressed.

### Application Example 6

The method of manufacturing a semiconductor device according to the application example further includes forming a silicon film constituting the thin film transistor, in which the first silicon oxide film, the silicon nitride film, the second silicon oxide film, and the silicon film are continuously formed in the same chamber.

According to this application example, the method of manufacturing a semiconductor device further includes forming a silicon film constituting the thin film transistor. The first silicon oxide film, the silicon nitride film, the second silicon oxide film, and the silicon film are continuously formed in the same chamber.

The continuous formation of the films in the same chamber represents that the films are formed while changing the gas material to be injected into the chamber without taking out the substrate from the chamber. At this time, the substrate is not put into or taken out from the chamber. Therefore, a period of time required to put or take out the substrate can be reduced. Accordingly, the semiconductor device can be manufactured with high productivity.

### BRIEF DESCRIPTION OF THE DRAWINGS

The invention will be described with reference to the accompanying drawings, wherein like numbers reference like elements.

FIG. 1 is a schematic diagram showing a structure of a semiconductor device according to a first embodiment.

FIG. 2 is a schematic side view showing a method of measuring the amount of warpage of the semiconductor device.

FIG. 3 is a graph illustrating a relationship between the thickness of agate electrode film and the amount of warpage of a substrate.

FIG. 4 is a graph showing a relationship between a nitrogen concentration in a silicon oxide film and an internal stress of the silicon oxide film.

FIG. 5 is a flowchart showing a method of manufacturing the semiconductor device.

FIG. 6 is a diagram showing the method of manufacturing the semiconductor device.

FIG. 7 is a diagram showing the method of manufacturing the semiconductor device.

FIG. 8 is a diagram showing the method of manufacturing the semiconductor device.

FIG. 9 is a diagram showing the method of manufacturing the semiconductor device.

FIG. 10 is a diagram showing the method of manufacturing the semiconductor device.

FIG. 11 is a diagram showing the method of manufacturing the semiconductor device.

FIG. 12 is a diagram showing the method of manufacturing the semiconductor device.

FIG. 13 is a diagram showing the method of manufacturing the semiconductor device.

FIG. 14 is a diagram showing the method of manufacturing the semiconductor device.

FIG. 15 is a diagram showing the method of manufacturing the semiconductor device.

FIG. 16 is a diagram showing the method of manufacturing the semiconductor device.

FIG. 17 is a schematic side sectional view showing a structure of an electrophoresis apparatus according to a second embodiment.

FIG. 18 is a schematic perspective view showing a structure of an electronic book according to a third embodiment.

FIG. 19 is a schematic perspective view showing a structure of a wristwatch.

### DESCRIPTION OF EXEMPLARY EMBODIMENTS

Hereinafter, an embodiment will be described with reference to the drawings. In the drawings, respective members are shown with different scales in order to make the sizes of the members recognizable in the drawings.

### First Embodiment

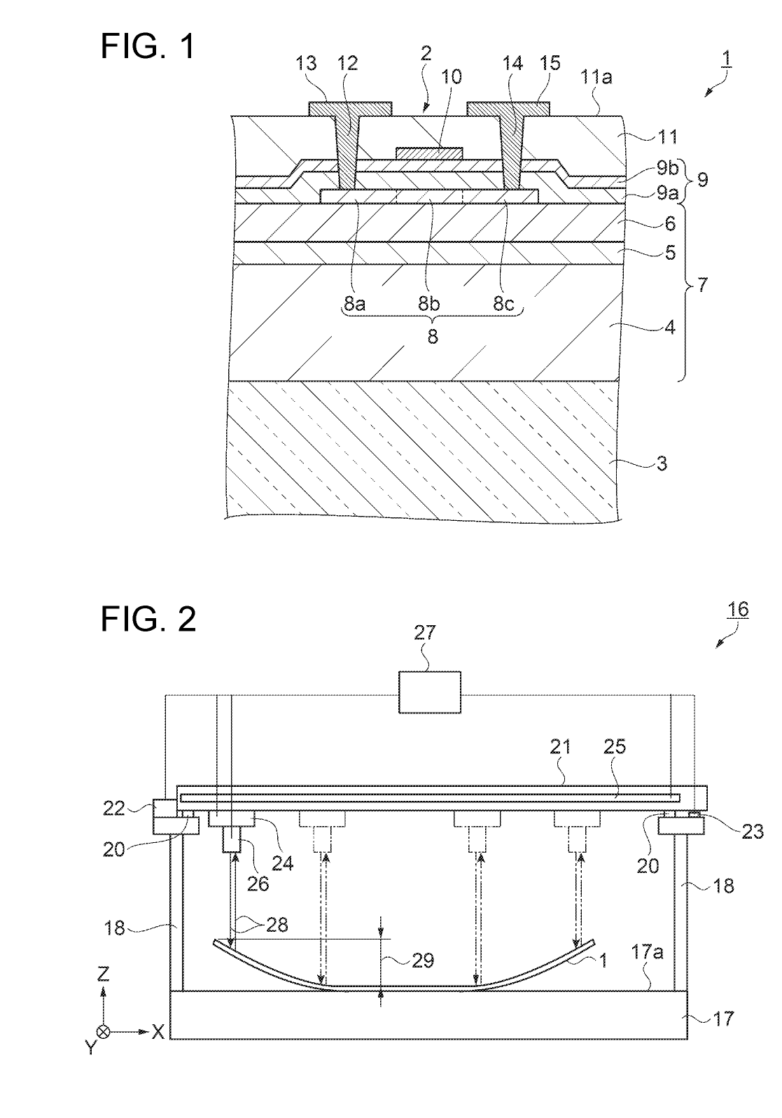

In an embodiment, a characteristic example of a semiconductor device and a method of manufacturing the semiconductor device will be described with reference to the drawings. The semiconductor device according to the first embodiment will be described with reference to FIGS. 1 to 4. FIG. 1 is a schematic diagram showing a structure of the semiconductor device. As shown in FIG. 1, the semiconductor device 1 includes a thin film transistor 2. The thin film transistor 2 will also be referred to as “TFT”. The semiconductor device 1 is applicable to, for example, a switching element of a display apparatus.

The semiconductor device 1 includes a substrate 3. A material of the substrate 3 is not particularly limited as long as it has insulating properties and rigidity. Further, in a case where the material of the substrate 3 has heat resistance, a heat treatment can be performed favorably. As the material of the substrate 3, for example, glass, plastic, ceramic, quartz, gallium arsenide, or silicon can be used. In the embodiment, for example, glass is used as the material of the substrate 3. The size and thickness of the substrate 3 are not particularly limited. In the embodiment, the substrate has, for example, a width of about 400 mm, a length of about 500 mm, and a thickness of about 0.5 mm.

A first silicon oxide film 4 is formed on the substrate 3. The first silicon oxide film 4 is provided to obtain a good balance between an electrical insulating function and stress generated by films formed on the substrate 3. The thickness of the first silicon oxide film 4 is not particularly limited and is, for example, about 800 nm in the embodiment. A film (not shown) may be formed between the substrate 3 and the first silicon oxide film 4.

A silicon nitride film 5 is formed on the first silicon oxide film 4. The silicon nitride film 5 is a dense film, and thus functions as a protective film that prevents permeation of water and prevents permeation of impurity ions such as sodium. The thickness of the silicon nitride film 5 is not particularly limited and is, for example, about 100 nm in the embodiment. A film (not shown) may be formed between the first silicon oxide film 4 and the silicon nitride film 5.

A second silicon oxide film 6 is formed on the silicon nitride film 5. The second silicon oxide film 6 is an underlayer of the thin film transistor 2 and has a low trap level. The second silicon oxide film 6 has a high nitrogen concentration of 3E²¹ atoms/cm³ or higher. By increasing the nitrogen concentration, the second silicon oxide film 6 suppresses permeation and diffusion of water. The thickness of the second silicon oxide film 6 is not particularly limited and is, for example, about 200 nm in the embodiment. A film (not shown) may be formed between the silicon nitride film 5 and the second silicon oxide film 6.

The first silicon oxide film 4, the silicon nitride film 5, and the second silicon oxide film 6 constitute the insulating film 7. The insulating film 7 is positioned between the substrate 3 and the thin film transistor 2 and suppresses electrical connection.

A semiconductor layer 8 is formed on the second silicon oxide film 6. The semiconductor layer 8 has a rectangular shape in a plan view when seen from a thickness direction of the substrate 3. The semiconductor layer 8 is divided into a source region 8a, a channel region 8b, and a drain region 8c in a longitudinal direction, and the channel region 8b is interposed between the source region 8a and the drain region 8c. A material of the semiconductor layer 8 is not particularly limited as long as the material can form a semiconductor. For example, silicon, germanium, gallium arsenide, gallium arsenide phosphide, gallium nitride, or silicon carbide can be used. In the embodiment, for example, polycrystalline silicon is used as the material of the semiconductor layer 8. Impurity ions are implanted into the source region 8a and the drain region 8c. The thickness of the semiconductor layer 8 is not particularly limited and is, for example, about 50 nm in the embodiment.

A gate insulating film 9 is provided to cover the semiconductor layer 8 and the second silicon oxide film 6. The gate insulating film 9 includes a first gate insulating film 9a and a second gate insulating film 9b. The first gate insulating film 9a is formed on the semiconductor layer 8 and the second silicon oxide film 6. The first gate insulating film 9a is a silicon oxide film and has a low nitrogen concentration. The nitrogen concentration in the first gate insulating film 9a is not particularly limited and is, for example, 2.8E²⁰ atoms/CC in the embodiment. The first gate insulating film 9a has high voltage resistance and high insulating properties.

The second gate insulating film 9b is formed on the first gate insulating film 9a. The second gate insulating film 9b is a silicon nitride film. The second gate insulating film 9b is a dense film that is rich in nitrogen, and thus functions as a protective film that prevents permeation of water and prevents permeation of impurity ions such as sodium. The thickness of the gate insulating film 9 is not particularly limited and is, for example, about 100 nm in the embodiment.

In a portion of the gate insulating film 9 opposite to the channel region 8b, a gate electrode 10 is formed. It is preferable that a material of the gate electrode 10 is a metal having a low resistance and a high melting point. In a case where the material of the gate electrode 10 has a high specific resistance, by increasing the thickness of the gate electrode 10 to decrease resistance, responsiveness of the thin film transistor 2 can be improved. In addition, by selecting the metal having a high melting point, a high-temperature manufacturing process can be used. As a material of the gate electrode 10, for example, molybdenum, titanium, tungsten, or chromium can be used. In the embodiment, for example, the gate electrode 10 includes molybdenum as the material. The melting point of the molybdenum is 2632° C., and molybdenum is a metal having a high melting point. Accordingly, a manufacturing process including a high-temperature process can be adopted.

In a case where impurity ions are implanted into the semiconductor layer 8, the gate electrode 10 functions as a mask that prevents the impurity ions from being implanted into the channel region 8b. Therefore, it is preferable that the thickness of the gate electrode 10 is 250 nm or more. The thickness of the gate electrode 10 is not particularly limited and is set as, for example, about 300 nm in the embodiment.

An upper insulating film 11 is formed to cover the gate insulating film 9 and the gate electrode 10. The upper insulating film 11 is also called an interlayer dielectric. The upper insulating film 11 may be a film formed of silicon oxide or may be a laminated film of a silicon oxide film and a silicon nitride film. The upper insulating film 11 functions not only as an insulating film for the thin film transistor 2 but also as a protective film. The thickness of the upper insulating film 11 is not particularly limited and is, for example, about 800 nm in the embodiment. In the embodiment, the upper insulating film 11 is a silicon oxide film and has a low nitrogen concentration. The nitrogen concentration in the upper insulating film 11 is not particularly limited and is, for example, 8.5E²⁰ atoms/CC in the embodiment. The upper insulating film 11 has high voltage resistance and high insulating properties.

In the upper insulating film 11, a surface opposite to the substrate 3 is an upper surface 11a. In a region of the semiconductor layer 8 from the source region 8a to the upper surface 11a, a source electrode 12 that penetrates the gate insulating film 9 and the upper insulating film 11 is formed. The source electrode 12 is connected to a source wiring 13 formed on the upper surface 11a. Likewise, in a region of the semiconductor layer 8 from the drain region 8c to the upper surface 11a, a drain electrode 14 that penetrates the gate insulating film 9 and the upper insulating film 11 is formed. The drain electrode 14 is connected to a drain wiring 15 formed on the upper surface 11a. The materials of the source electrode 12, the source wiring 13, the drain electrode 14, and the drain wiring 15 are not particularly limited as long as they are conductive metals. For example, in the embodiment, a film in which titanium, aluminum, and titanium are laminated in this order is used.

The thin film transistor 2 includes the semiconductor layer 8, the gate insulating film 9, the gate electrode 10, the source electrode 12, and the drain electrode 14. The insulating film 7 is disposed between the substrate 3 and the thin film transistor 2.

FIG. 2 is a schematic side view showing a method of measuring the amount of warpage of the semiconductor device. As shown in FIG. 2, a warpage measuring device 16 is used in order to measure the amount of warpage of the semiconductor device 1. The warpage measuring device 16 includes a surface plate 17, and the semiconductor device 1 as a measurement target is disposed on the surface plate 17. The surface plate 17 is formed such that flatness of the upper surface 17a is accurate. Among directions moving along a plane of the upper surface 17a, a right direction in the drawing will be referred to as “+X direction”, and a direction perpendicular to the X direction will be referred to as “Y direction”. A normal direction of the upper surface 17a that faces upward in the drawing will be referred to as “+Z direction”.

A surface that protrudes in a case where the semiconductor device 1 warps is made to face a −Z direction. The semiconductor device 1 is disposed on the surface plate 17 such that the protruding surface comes into contact with the upper surface 17a. A form in the semiconductor device 1 warps is not particularly limited. In a case where the semiconductor device 1 is rectangular, the semiconductor device 1 is likely to warp in a form similar to a part of a cylindrical shape in many cases.

A pair of support portions 18 that extend in the +Z direction is vertically provided on the upper surface 17a of the surface plate 17. A first rail 20 that extends in the Y direction is provided on a surface of each of the support portions 18 on the +Z direction side. A second rail 21 that extends in the X direction is provided on the first rail 20. On a surface of the second rail 21 on the −X direction side, a linear motion mechanism 22 that moves the second rail 21 in the Y direction is provided. Further, a first scale 23 is provided on the support portion 18 on the +X direction side. The first scale 23 detects a position of the second rail 21 in the Y direction, converts the position of the second rail 21 in the Y direction into an electric signal, and outputs the electric signal.

A carriage 24 that moves along the second rail 21 is provided on the second rail 21. A linear motion mechanism is built into the carriage 24, and the carriage 24 is movable in the X direction. As the linear motion mechanism 22 and the linear motion mechanism built into the carriage 24, for example, a ball screw can be used. A second scale 25 that detects a position of the carriage 24 is provided on the second rail 21. The second scale 25 converts the position of the carriage 24 into an electric signal and outputs the electric signal.

A non-contact distance sensor 26 is provided on a surface of the carriage 24 on the −Z direction. A sensing method of the non-contact distance sensor 26 is not particularly limited. For example, an optical method or a capacitive method can be used. In the embodiment, for example, an optical sensor using laser light is used as the non-contact distance sensor 26.

The warpage measuring device 16 includes a control device 27, and the linear motion mechanism 22, the first scale 23, the carriage 24, the second scale 25, and the non-contact distance sensor 26 are connected to the control device 27. The control device 27 moves the non-contact distance sensor 26 to a predetermined position and emits laser light 28 from the non-contact distance sensor 26 in the −Z direction. The laser light 28 emitted from the non-contact distance sensor 26 irradiates the semiconductor device 1. The laser light 28 that reaches the semiconductor device 1 is reflected from the semiconductor device 1. The non-contact distance sensor 26 receives the laser light 28 reflected from the semiconductor device 1 and detects a change in phase.

The non-contact distance sensor 26 calculates the distance between the non-contact distance sensor 26 and the semiconductor device 1 based on the change in the phase of the laser light 28, and outputs the calculated distance to the control device 27. The control device 27 moves the non-contact distance sensor 26 at a predetermined interval in the X direction and the Y direction. At each portion, the distance between the non-contact distance sensor 26 and the semiconductor device 1 is measured. Next, the control device 27 detects a shape of the semiconductor device 1 and determines a portion where the semiconductor device 1 is most distant from the surface plate 17 and a portion where the semiconductor device 1 is closest to the surface plate 17. A difference between the portion where the semiconductor device 1 is most distant from the surface plate 17 and the portion where the semiconductor device 1 is closest to the surface plate 17 in the Z direction is calculated as an amount of warpage 29 in the semiconductor device 1.

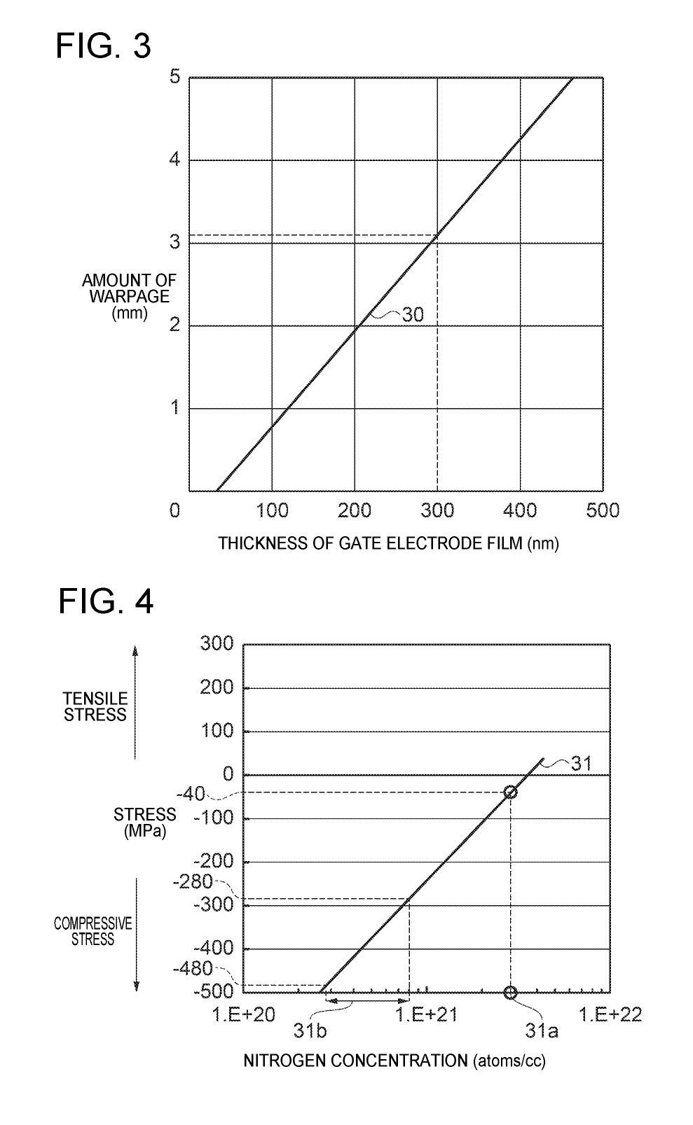

FIG. 3 is a graph illustrating a relationship between the thickness of the gate electrode film and the amount of warpage of the substrate. In FIG. 3, the horizontal axis represents the thickness of a gate electrode film, and the vertical axis represents the amount of warpage of the substrate. The gate electrode film is formed by sputtering using molybdenum. The gate electrode 10 is a portion of the gate electrode film that is formed by patterning the gate electrode film. A stress of the gate electrode film changes depending on film forming conditions. In a case where the optimum film is obtained by adjusting the film forming conditions, the stress is +900 MPa to +500 MPa. A thickness-warpage correlation line 30 shows a correlation between the thickness of the gate electrode film and the amount of warpage of the substrate 3. The amount of warpage of the substrate 3 is proportional to a value obtained by multiplying the film stress of the gate electrode film and the thickness of the gate electrode film. The thickness-warpage correlation line 30 shows a correlation in a case where the stress of the gate electrode film is +900 MPa. Accordingly, the amount of warpage of the substrate 3 is proportional to the thickness of the gate electrode film. In the embodiment, the thickness of the gate electrode film is 300 nm. Therefore, the average amount of warpage of the substrate 3 is about 3 mm.

FIG. 4 is a graph showing a relationship between a nitrogen concentration in a silicon oxide film and an internal stress of the silicon oxide film. In FIG. 4, the horizontal axis represents the nitrogen concentration in the silicon oxide film. The silicon oxide film corresponds to the first gate insulating film 9a, the first silicon oxide film 4, and the second silicon oxide film 6. The nitrogen concentration is expressed in units of “atoms/CC”. CC represents one cubic centimeter, and thus “atoms/CC” is the same as “atoms/cm³”. The vertical axis represents the internal stress of the silicon oxide film. The upper side of the vertical axis in the drawing represents a tensile stress, and the symbol of a value of the tensile stress is “+”. The lower side of the vertical axis in the drawing represents a compressive stress, and the symbol of a value of the compressive stress is “−”.

The internal stress of the silicon oxide film is obtained by measuring a difference between the deformation amounts of the substrate before and after the formation of the silicon oxide film using a flatness tester and calculating the internal stress based on the thickness of the substrate and the measured difference in deformation amount. As the flatness tester, for example, a device that analyzes an image of an interference fringe obtained by a laser oblique incidence interferometer to calculate a deformation amount can be used.

A nitrogen concentration-stress correlation line 31 shows a relationship between the nitrogen concentration in the silicon oxide film and the internal stress of the silicon oxide film. As indicated by the nitrogen concentration-stress correlation line 31, the internal stress of the silicon oxide film is −40 MPa to 0 MPa in the vicinity of a nitrogen concentration of 3E²¹ atoms/CC to 4E²¹ atoms/CC. Under a first condition 31a where the nitrogen concentration is in the vicinity of 3E²¹ atoms/CC, water is not likely to permeate and diffuse into the silicon oxide film. In a case where the second silicon oxide film 6 includes water, there are effects on characteristics of the thin film transistor 2. The first condition 31a where the nitrogen concentration is high is applied to the second silicon oxide film 6.

By setting the nitrogen concentration in the second silicon oxide film 6 coming into contact with the semiconductor layer 8 to be high, the trap level is decreased. Therefore, accumulation of + charges can be suppressed. Deterioration in the performance of the thin film transistor 2 can be suppressed. In addition, the silicon oxide film having a high nitrogen concentration has a high blocking effect against impurity ions. Therefore, a variation in the characteristics of the thin film transistor 2 caused by impurity ions can be suppressed.

Accordingly, the second silicon oxide film 6 has a low internal stress. Under the first condition 31a, a compressive stress of −40 MPa is applied to the second silicon oxide film 6. Therefore, by increasing the thickness of the second silicon oxide film 6, the amount of warpage of the substrate 3 of 3 mm can be reduced. In order to reduce the warpage of the substrate 3 by increasing the thickness of the second silicon oxide film 6 without forming the first silicon oxide film 4, it is necessary that the thickness of the second silicon oxide film 6 is about 7 μm. At this time, a period of time required to form the second silicon oxide film 6 is about 40 minutes, and thus the productivity significantly deteriorates.

In the semiconductor device 1, the first silicon oxide film 4 is formed without increasing the thickness of the second silicon oxide film 6. The nitrogen concentration in the first silicon oxide film 4 is lower than that in the second silicon oxide film 6. In the first silicon oxide film 4 having a low nitrogen concentration, the compressive stress can be increased to be higher than that of the second silicon oxide film 6. Accordingly, even in a case where the gate electrode film used in the thin film transistor 2 has a tensile stress, the stress can be well-balanced by the first silicon oxide film 4. As a result, an increase in the warpage of the semiconductor device 1 can be suppressed.

It is preferable that the nitrogen concentration in the first silicon oxide film 4 is under a second condition 31b where the nitrogen concentration is 3E²⁰ atoms/CC to 9E²⁰ atoms/CC. At this time, the stress of the first silicon oxide film 4 can be made to be a compressive stress, and the value of the compressive stress can be made to be 280 MPa to 480 MPa. As a result, even in a case where the gate electrode film is provided, the amount of warpage of the substrate 3 can be reduced. In the gate electrode 10, a tensile stress is likely to be generated from a film formed of molybdenum. Even in a case where the film formed of molybdenum is provided in the substrate 3, the stress can be well-balanced by the first silicon oxide film 4. Therefore, the warpage of the substrate 3 can be suppressed.

By making the nitrogen concentration in the first silicon oxide film 4 to be under the second condition 31b, the thickness of the first silicon oxide film 4 can be made to be 800 nm. Accordingly, the semiconductor device 1 can be manufactured with high productivity.

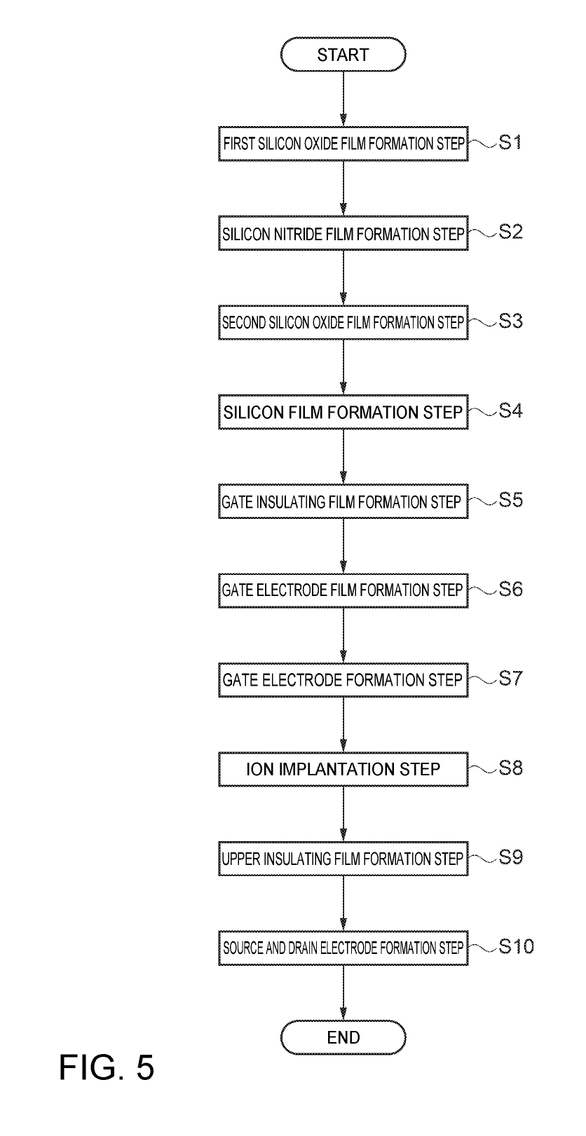

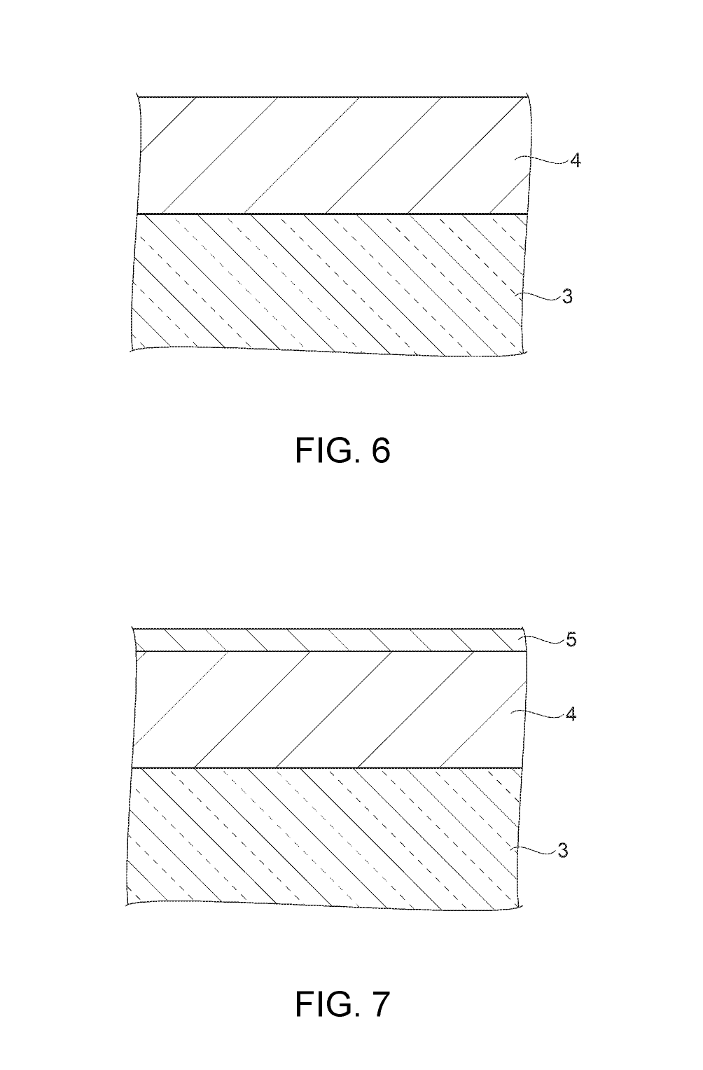

Next, a method of manufacturing the semiconductor device 1 will be described using FIGS. 5 to 16. FIG. 5 is a flowchart showing the method of manufacturing the semiconductor device. FIGS. 6 to 16 are diagrams showing the method of manufacturing the semiconductor device.

In the flowchart of FIG. 5, Step S1 corresponds to a first silicon oxide film formation step of forming the first silicon oxide film 4 on the substrate 3 using silane gas and nitrogen oxide gas. Next, the process proceeds to Step S2. Step S2 is a silicon nitride film formation step of forming the silicon nitride film 5 on the first silicon oxide film 4. Next, the process proceeds to Step S3. Step S3 is a second silicon oxide film formation step of forming the second silicon oxide film 6 on the nitrogen oxide gas 5 using silane gas and nitrogen oxide gas. Next, the process proceeds to Step S4.

Step S4 is a silicon film formation step of forming a silicon film on the second silicon oxide film 6. In this step, the silicon film is formed in a shape of the semiconductor layer 8. Next, the process proceeds to Step S5. Step S5 is a gate insulating film formation step of forming the gate insulating film 9 on the silicon film and the second silicon oxide film 6. Next, the process proceeds to Step S6. Step S6 is a gate electrode film formation step of forming the gate electrode film on the gate insulating film 9. Next, the process proceeds to Step S7. Step S7 is a gate electrode formation step of patterning the gate electrode film to form the gate electrode 10. Next, the process proceeds to Step S8. Step S8 is an ion implantation step of implanting impurity ions into the silicon film. Next, the process proceeds to Step S9. Step S9 is an upper insulating film formation step of forming the upper insulating film 11 on the gate insulating film 9 and the gate electrode 10. Next, the process proceeds to Step S10. Step S10 is a source and drain electrode formation step of forming the source electrode 12, the drain electrode 14, and the like. Through the above-described steps, the semiconductor device 1 is completed.

Next, the manufacturing method will be described in detail using FIGS. 6 to 16 corresponding to the steps shown in FIG. 5, respectively.

FIG. 6 is a diagram corresponding to the first silicon oxide film formation step of Step S1. As shown in FIG. 6, the substrate 3 is prepared in Step S1. As the substrate 3, a plate obtained by grinding and polishing a glass plate in a predetermined thickness to reduce the surface roughness is used.

The substrate 3 is provided in a chamber of a plasma-enhanced chemical vapor deposition (PECVD) device.

Gas including silane gas (SiH₄) and nitrogen oxide gas (N₂O) is injected into the chamber, and a high frequency or the like is applied thereto. As a result, a plasma is generated from the raw material gases, and a chemical reaction is activated. At this time, by adjusting the flow rate of each of the raw material gases and adjusting electric power applied to an electrode provided in the chamber, the nitrogen concentration in the silicon oxide is adjusted to be under the second condition 31b.

In a case where a ratio of the concentration of the silane gas (SiH₄) to the concentration of the nitrogen oxide gas (N₂O) is low, the nitrogen concentration in the silicon oxide can be reduced compared to a case where the ratio of the concentration of the silane gas (SiH₄) to the concentration of the nitrogen oxide gas (N₂O) is high. In the first silicon oxide film formation step of Step S1 of forming the first silicon oxide film 4, the ratio of the concentration of the silane gas (SiH₄) to the concentration of the nitrogen oxide gas (N₂O) is lower than that in the second silicon oxide film formation step of Step S3 of forming the second silicon oxide film 6. As a result, the nitrogen concentration in the silicon oxide of the first silicon oxide film 4 can be made to be lower than that in the second silicon oxide film 6. Further, in a case where a case where the applied electric power is high, the nitrogen concentration in the silicon oxide can be reduced compared to a case where the applied electric power is low. The silicon oxide film having a low nitrogen concentration can increase the compressive stress. Accordingly, even in a case where a film formed of molybdenum having a high tensile stress is provided in the substrate 3 in a post step, the warpage of the substrate 3 can be suppressed.

FIG. 7 is a diagram corresponding to the silicon nitride film formation step of Step S2. As shown in FIG. 7, in Step S2, the silicon nitride film 5 is formed on the first silicon oxide film 4. Gas including silane gas (SiH₄) and ammonia gas (NH₃) is injected into the chamber of the PECVD device, and a high frequency or the like is applied thereto. As a result, a plasma is generated from the raw material gases, and a chemical reaction is activated. Thus, the silicon nitride film 5 is formed on the first silicon oxide film 4.

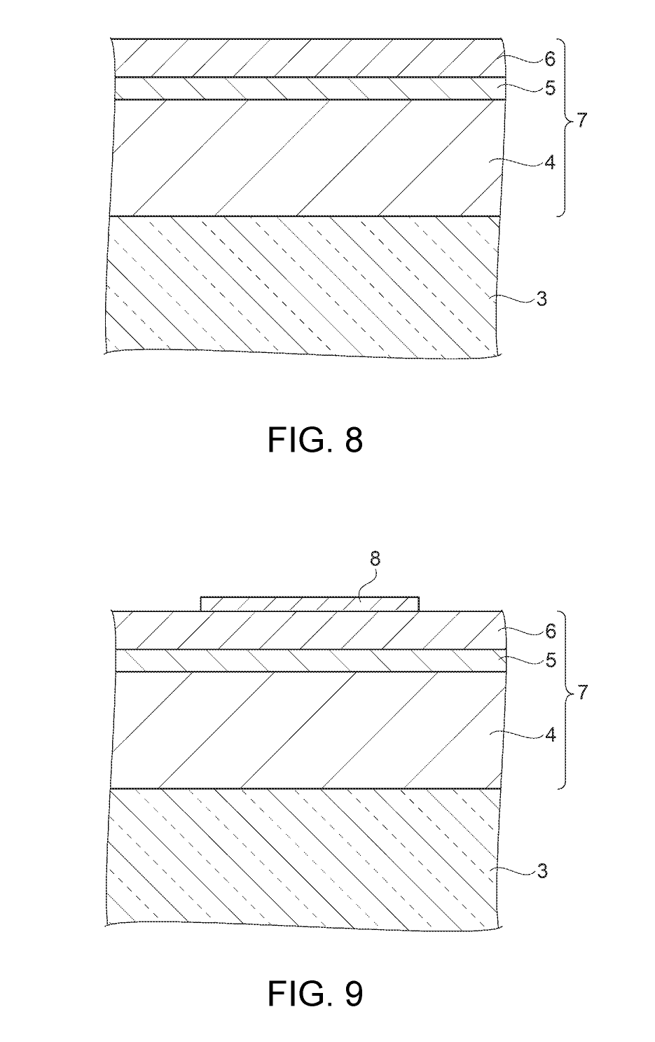

FIG. 8 is a diagram corresponding to the second silicon oxide film formation step of Step S3. As shown in FIG. 8, in Step S3, the second silicon oxide film 6 is formed on the silicon nitride film 5. Gas including silane gas (SiH₄) and nitrogen oxide gas (N₂O) is injected into the chamber of the PECVD device, and a high frequency or the like is applied thereto. As a result, a plasma is generated from the raw material gases, and a chemical reaction is activated. Thus, the second silicon oxide film 6 is formed on the silicon nitride film 5.

In the second silicon oxide film formation step of Step S3 of forming the second silicon oxide film 6, the ratio of the concentration of the silane gas (SiH₄) to the concentration of the nitrogen oxide gas (N₂O) is higher than that in the first silicon oxide film formation step of Step S1 of forming the first silicon oxide film 4. As a result, the nitrogen concentration in the silicon oxide of the second silicon oxide film 6 can be made to be higher than that in the first silicon oxide film 4. At this time, by adjusting the flow rate of each of the raw material gases and adjusting electric power that is applied to an electrode provided in the chamber, the nitrogen concentration in the silicon oxide is adjusted to be under the first condition 31a. Through the steps until Step S3, the insulating film 7 is completed.

FIG. 9 is a diagram corresponding to the silicon film formation step of Step S4. As shown in FIG. 9, in Step S4, the semiconductor layer 8 is formed on the insulating film 7. First, gas including silane gas (SiH₄) is injected into the chamber of the PECVD device, and a high frequency or the like is applied thereto. As a result, a plasma is generated from the raw material gases, and a chemical reaction is activated. As a result, an amorphous silicon film having a thickness of about 50 nm is formed on the second silicon oxide film 6. Next, the amorphous silicon film is crystallized using a laser crystallization method or the like to form a polycrystalline silicon film. Next, the semiconductor layer 8 that is the polycrystalline silicon film having an island shape is formed using a photolithography method or the like. The semiconductor layer 8 is the silicon film for manufacturing the thin film transistor 2.

The step of forming the first silicon oxide film 4 of Step S1, the step of forming the silicon nitride film 5 of Step S2, the step of forming the second silicon oxide film 6 of Step S3, and the step of forming the silicon film of Step S4 may be continuously formed in the same chamber. That is, the first silicon oxide film 4, the silicon nitride film 5, the second silicon oxide film 6, and the silicon film of Step S4 may be continuously formed in the same chamber. In the step of forming the silicon film of Step S4, the silicon film refers to the amorphous silicon film. By adjusting the kind and flow rate of gas injected to the chamber and electric power that is applied to an electrode provided in the chamber, the film of each of the steps can be formed.

The continuous formation of the films in the same chamber represents that the films are formed while changing the gas material to be injected into the chamber without taking out the substrate 3 from the chamber. At this time, the substrate 3 is not put into or taken out from the chamber. Therefore, a period of time required to put or take out the substrate 3 can be reduced. Accordingly, the semiconductor device 1 can be manufactured with high productivity. In addition, adherence of dust to the substrate 3 caused during putting into or taking out from the chamber can be suppressed.

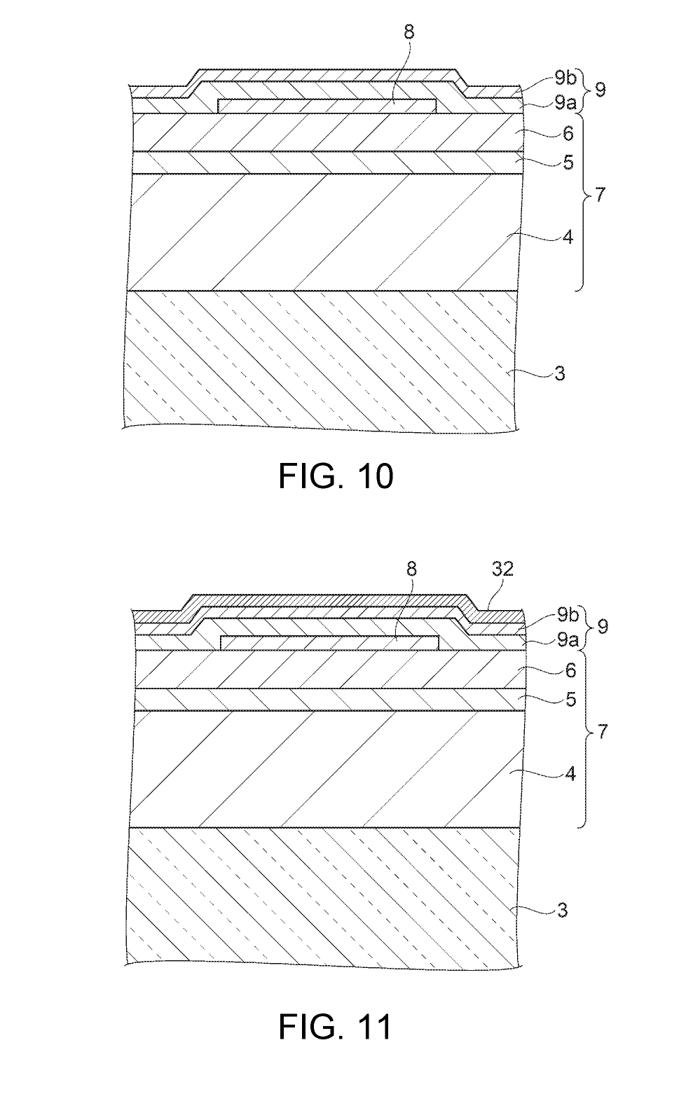

FIG. 10 is a diagram corresponding to the gate insulating film formation step of Step S5. As shown in FIG. 10, in Step S5, the gate insulating film 9 is formed on the semiconductor layer 8 and the second silicon oxide film 6. First, the first gate insulating film 9a is formed. The first gate insulating film 9a is a silicon oxide film. The substrate 3 on which the semiconductor layer 8 is formed is provided in the chamber of the PECVD device. Gas including silane gas (SiH₄) and nitrogen oxide gas (N₂O) is injected into the chamber of the PECVD device, and a high frequency or the like is applied thereto. As a result, a plasma is generated from the raw material gases, and a chemical reaction is activated. Thus, the first gate insulating film 9a is formed on the second silicon oxide film 6 and the semiconductor layer 8.

Next, the second gate insulating film 9b is formed. The second gate insulating film 9b is a silicon nitride film. Gas including silane gas (SiH₄) and ammonia gas (NH₃) is injected into the chamber of the PECVD device, and a high frequency or the like is applied thereto. As a result, a plasma is generated from the raw material gases, and a chemical reaction is activated. As a result, the second gate insulating film 9b is formed on the first gate insulating film 9a. Through the above-described procedure, the gate insulating film 9 is formed.

FIG. 11 is a diagram corresponding to the gate electrode film formation step of Step S6. As shown in FIG. 11, in Step S6, the gate electrode film 32 is formed on the gate insulating film 9. The gate electrode film 32 forms a base of the gate electrode 10 and is formed of molybdenum. The substrate 3 on which the gate insulating film 9 is formed is provided in a chamber of a sputtering deposition device. The film formed of molybdenum is formed on the gate insulating film 9 using a sputtering method.

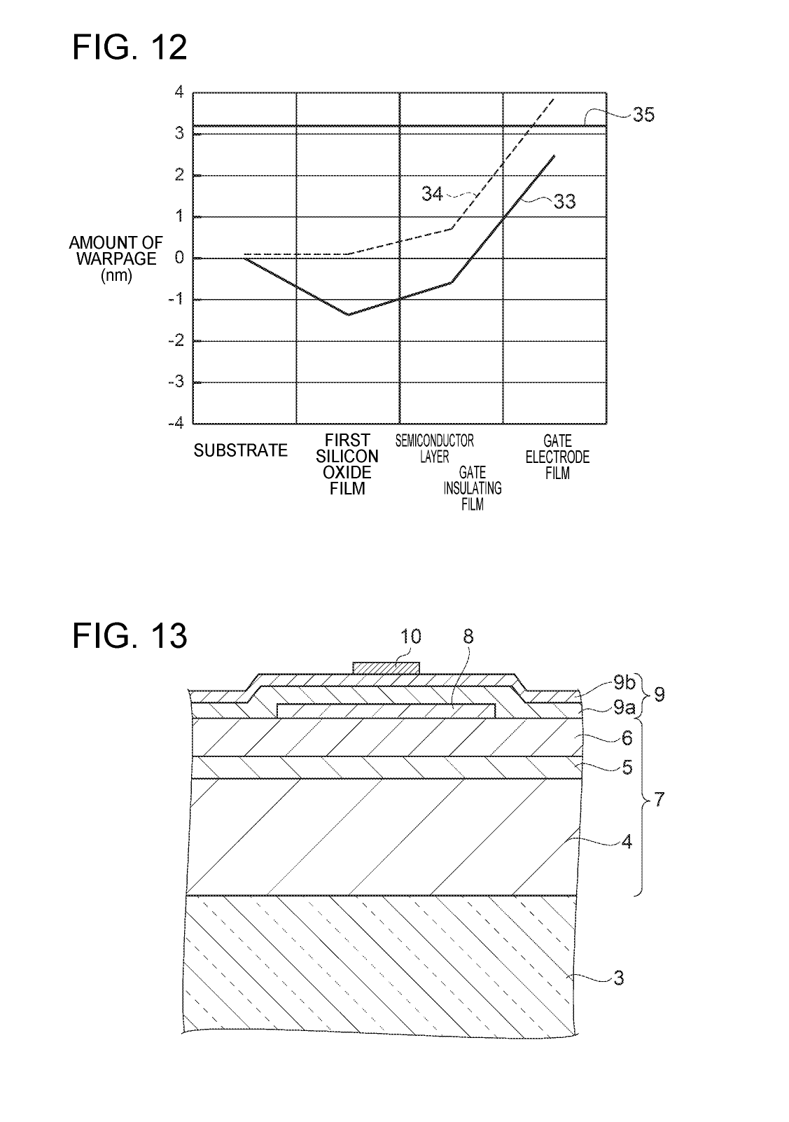

FIG. 12 is a diagram showing the amount of warpage of the substrate that changes along with the transition of the manufacturing process. In FIG. 12, the horizontal axis represents four steps, and the vertical axis represents the amount of warpage of the substrate 3 in each of the steps. A first transition line 33 shows transition of the amount of warpage of the substrate 3 in a case where the first silicon oxide film 4 is provided between the substrate 3 and the silicon nitride film 5. As a comparative example, a second transition line 34 represents transition of the amount of warpage of the substrate 3 in a case where the first silicon oxide film 4 is not provided.

A determination line 35 represents a value which determines whether or not a transport device that transports the substrate 3 to a device used in the next step can hold the substrate 3 in Step S6. The transport device includes an air chuck mechanism that sucks the substrate 3, and holds the substrate 3 using the air chuck mechanism. At this time, in a case where the amount of warpage of the substrate 3 is more than the determination line 35, air leaks between the air chuck mechanism and the substrate 3. Therefore, the air chuck mechanism cannot suck the substrate 3, and thus the transport device cannot stably hold the substrate 3. In a case where the amount of warpage of the substrate 3 is less than the determination line 35, the transport device can stably transport the substrate 3. Accordingly, it is preferable that the amount of warpage of the substrate 3 is less than the determination line 35.

As indicated by the first transition line 33, before the formation of the substrate 3, the amount of warpage is 0, and the substrate 3 does not warp. Next, after forming the first silicon oxide film 4 on the substrate 3, the substrate 3 warps by about −1.4 mm. The internal stress of the first silicon oxide film 4 is a compressive stress, and a surface of the substrate 3 where the first silicon oxide film 4 is provided protrudes and warps.

After providing the semiconductor layer 8 and the gate insulating film 9 on the insulating film 7, the amount of warpage of the substrate 3 is reduced up to −0.8 mm. The reason for this is that the internal stress of the semiconductor layer 8 is a tensile stress and the substrate 3 is affected by the tensile stress.

After forming the gate electrode film 32 on the gate insulating film 9, the amount of warpage of the substrate 3 increases up to 2.5 mm. The internal stress of the gate electrode film 32 is a tensile stress, and a surface of the substrate 3 where the gate electrode film 32 is provided is recessed. A determination value of the amount of warpage indicated by the determination line 35 is 3.2 mm. Accordingly, the amount of warpage of the substrate 3 is less than the determination line 35. Therefore, the transport device can stably hold the substrate 3.

As indicated by the second transition line 34 in the comparative example, in a case where the first silicon oxide film 4 is not formed, the silicon nitride film 5, the second silicon oxide film 6, the semiconductor layer 8, and the gate insulating film 9 are provided on the substrate 3. At this time, the amount of warpage of the substrate 3 is +0.8 mm. After providing the gate electrode film 32 on the gate insulating film 9, the amount of warpage of the substrate 3 increases up to 3.8 mm. The internal stress of the gate electrode film 32 is a tensile stress, and a surface of the substrate 3 where the gate electrode film 32 is provided is recessed. A determination value of the amount of warpage indicated by the determination line 35 is 3.2 mm. Accordingly, the amount of warpage of the substrate 3 is more than the determination line 35. Therefore, the transport device cannot stably hold the substrate 3. As a result, the transportation operation of the transport device may fail.

As clearly seen from a comparison between the first transition line 33 and the second transition line 34, the amount of warpage of the substrate 3 after the formation of the gate electrode film 32 is reduced by providing the first silicon oxide film 4. The amount of warpage of the substrate 3 is less than the determination line 35. Therefore, the transport device can stably transport the substrate 3.

FIG. 13 is a diagram corresponding to the gate electrode formation step of Step S7. As shown in FIG. 13, in Step S7, the gate electrode film 32 is formed in a shape of the gate electrode 10 having an island shape. Using a photolithography method, the gate electrode film 32 is patterned in the shape of the gate electrode 10. Since the area of the gate electrode film 32 is reduced, the warpage of the substrate 3 is also reduced.

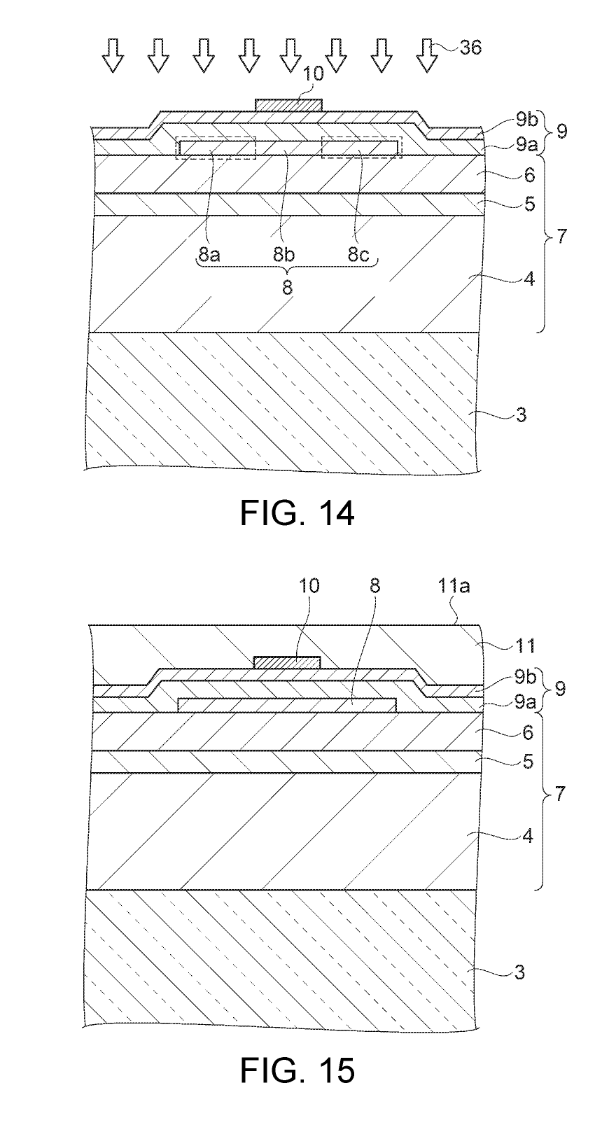

FIG. 14 is a diagram corresponding to the ion implantation step of Step S8. As shown in FIG. 14, in Step S8, impurity ions 36 are implanted into the semiconductor layer 8 using an ion implantation method. Portions of the semiconductor layer 8 into which the impurity ions 36 are implanted become the source region 8a and the drain region 8c. This way, the source region 8a, the drain region 8c, and the channel region 8b are formed on the semiconductor layer 8. The gate electrode 10 functions as a mask that suppresses the implantation of the impurity ions into the channel region 8b. Therefore, the thickness of the gate electrode 10 is set to be 250 nm or more. Accordingly, the thickness of the gate electrode film 32 is 250 nm or more, which causes an increase in the amount of warpage of the substrate 3.

FIG. 15 is a diagram corresponding to the upper insulating film formation step of Step S9. As shown in FIG. 15, in Step S9, the upper insulating film 11 is formed. The upper insulating film 11 is a silicon oxide film. The substrate 3 is provided in the chamber of the PECVD device. Gas including silane gas (SiH₄) and nitrogen oxide gas (N₂O) is injected into the chamber of the PECVD device, and a high frequency or the like is applied thereto. As a result, a plasma is generated from the raw material gases, and a chemical reaction is activated. Thus, the upper insulating film 11 is formed on the gate insulating film 9 and the gate electrode 10.

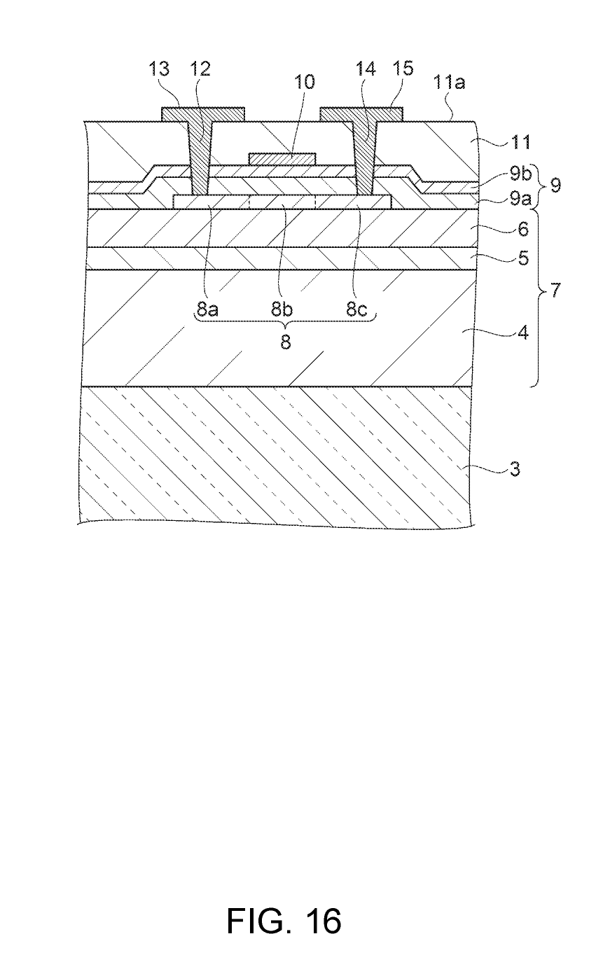

FIG. 16 is a diagram corresponding to the source and drain electrode formation step of Step S10. As shown in FIG. 16, in Step S10, a contact hole that reaches the source region 8a and a contact hole that reaches the drain region 8c are formed in the gate insulating film 9 and the upper insulating film 11. Next, on the upper surface 11a of the upper insulating film 11 and in the contact holes, a molybdenum wiring film having a thickness of 500 nm is formed using a sputtering method or the like. Next, the molybdenum wiring film is patterned using a photolithography method to form the source electrode 12, the source wiring 13, the drain electrode 14, and the drain wiring 15. Through the above-described steps, the semiconductor device 1 is completed.

As described above, according to the embodiment, the following effects are obtained.

(1) According to the embodiment, the semiconductor device 1 includes the substrate 3 and the thin film transistor 2. The insulating film 7 is disposed between the substrate 3 and the thin film transistor 2. The insulating film 7 suppresses the flow of an unnecessary current that changes the characteristics of the thin film transistor 2. In the insulating film 7, the first silicon oxide film 4, the silicon nitride film 5, and the second silicon oxide film 6 are disposed in this order.

The second silicon oxide film 6 is positioned close to the thin film transistor 2 and has a high nitrogen concentration. The silicon oxide film having a high nitrogen concentration has a low trap level, and thus accumulation of + charges is suppressed. Deterioration in the performance of the thin film transistor 2 can be suppressed.

The silicon nitride film 5 has a high blocking effect against impurity ions. Therefore, a variation in the characteristics of the thin film transistor 2 caused by impurity ions can be suppressed. The first silicon oxide film 4 has a low nitrogen concentration. The silicon oxide film having a low nitrogen concentration can increase the compressive stress. Accordingly, even in a case where the thin film transistor 2 has a tensile stress, the stress can be well-balanced by the first silicon oxide film 4. As a result, an increase in the warpage of the semiconductor device 1 can be suppressed.

(2) According to the embodiment, the nitrogen concentration in the first silicon oxide film 4 is 3E²⁰ atoms/CC to 9E²⁰ atoms/CC. At this time, the stress of the first silicon oxide film 4 can be made to be a compressive stress and can be made to be 280 MPa to 480 MPa.

(3) According to the embodiment, the gate electrode 10 in the thin film transistor 2 includes molybdenum. Molybdenum is a metal having a high melting point. Accordingly, a manufacturing process including a high-temperature process can be adopted. Molybdenum has a higher electrical specific resistance than aluminum or copper. However, by increasing the thickness of the gate electrode 10, the resistance can be suppressed to be low. In a case where the thickness of the gate electrode film 32 formed of molybdenum is large, a tensile stress is likely to be generated from the gate electrode film 32 formed of molybdenum. Even in a case where the gate electrode film 32 formed of molybdenum is provided in the substrate 3, the stress can be well-balanced by the first silicon oxide film 4. Therefore, the warpage of the substrate 3 can be suppressed.

(4) According to the embodiment, the method of manufacturing the semiconductor device 1 includes the step of forming the first silicon oxide film 4 of Step S1, the step of forming the silicon nitride film 5 of Step S2, and the step of forming the second silicon oxide film 6 of Step S3. In the step of forming the first silicon oxide film 4 of Step S1 and the step of forming the second silicon oxide film 6 of Step S3, silane gas (SiH₄) and nitrogen oxide gas (N₂O) are used.

In the step of forming the first silicon oxide film 4 of Step S1, the ratio of the concentration of the silane gas (SiH₄) to the concentration of the nitrogen oxide gas (N₂O) is lower than that in the step of forming the second silicon oxide film 6 of Step S3. This way, by controlling the ratio of the concentration of the silane gas (SiH₄) to the concentration of the nitrogen oxide gas (N₂O), the semiconductor device 1 in which the nitrogen concentration in the first silicon oxide film 4 is lower than that of the second silicon oxide film 6 can be manufactured. Further, by increasing electric power applied to an electrode in the chamber, the nitrogen concentration in the first silicon oxide film 4 can be reduced compared to a case where the electric power is low.

The silicon oxide film having a low nitrogen concentration can increase the compressive stress. Accordingly, even in a case where the gate electrode film 32 having a high tensile stress is provided in the substrate 3 in a post step, the warpage of the substrate 3 can be suppressed.

(5) According to the embodiment, the method of manufacturing the semiconductor device 1 further includes a step of forming the semiconductor layer 8 in the silicon film formation step of Step S4 in order to manufacture the thin film transistor 2. The first silicon oxide film 4, the silicon nitride film 5, the second silicon oxide film 6, and the silicon film that forms a base of the semiconductor layer 8 to be formed in Step S4 are continuously formed in the same chamber.

The continuous formation of the films in the same chamber represents that the films are formed while changing the gas material to be injected into the chamber without taking out the substrate 3 from the chamber. At this time, the substrate 3 is not put into or taken out from the chamber. Therefore, a period of time required to put or take out the substrate 3 can be reduced. Accordingly, the semiconductor device 1 can be manufactured with high productivity.

### Second Embodiment

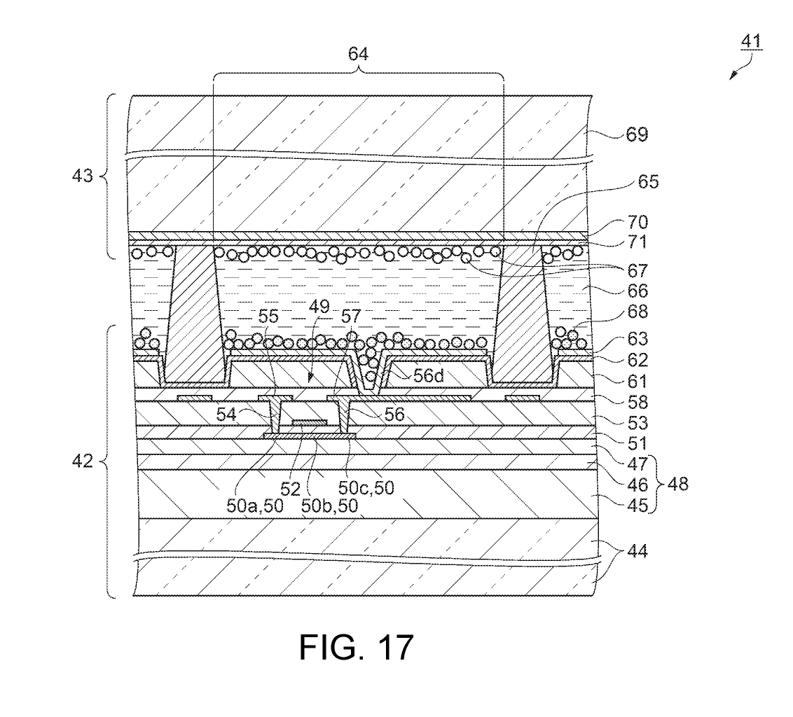

Next, an embodiment of an electrophoresis apparatus in which the semiconductor device 1 is provided will be described using a schematic side sectional view of FIG. 17 showing a structure of the electrophoresis apparatus. The electrophoresis apparatus according to the embodiment is an example of an electronic apparatus in which the semiconductor device 1 according to the first embodiment is provided. The same features as those in the first embodiment will not be repeated.

As shown in FIG. 17, in an electrophoresis apparatus 41 as the electronic apparatus, a first substrate 42 as the semiconductor device and a second substrate 43 are provided to overlap each other. The first substrate 42 includes a first base material 44 as a substrate. The first base material 44 is a glass plate. A first silicon oxide film 45, a silicon nitride film 46, and a second silicon oxide film 47 are set to overlap each other in this order on the first base material 44. The first silicon oxide film 45, the silicon nitride film 46, and the second silicon oxide film 47 constitute an insulating film 48.

The first silicon oxide film 45 corresponds to the first silicon oxide film 4 according to the first embodiment, and the silicon nitride film 46 corresponds to the silicon nitride film 5 according to the first embodiment. The second silicon oxide film 47 corresponds to the second silicon oxide film 6 according to the first embodiment. Accordingly, the nitrogen concentration in the first silicon oxide film 45 is 3E²⁰ atoms/CC to 9E²⁰ atoms/CC, and the nitrogen concentration in the second silicon oxide film 47 is in the vicinity of 3E²¹ atoms/CC to 4E²¹ atoms/CC.

A thin film transistor 49 is provided on the insulating film 48, and the thin film transistor 49 has the same structure as the thin film transistor 2 according to the first embodiment. The thin film transistor 49 is a switching element. A semiconductor layer 50, a gate insulating film 51, a gate electrode 52, and an upper insulating film 53 are provided to overlap each other on the insulating film 48. The semiconductor layer 50 includes a source region 50a, a channel region 50b, and a drain region 50c.

A source electrode 54 that penetrates the gate insulating film 51 and the upper insulating film 53 is connected to the source region 50a. A source wiring 55 is provided on the upper insulating film 53, and the source electrode 54 connects the source region 50a and the source wiring 55 to each other. Likewise, a drain electrode 56 that penetrates the gate insulating film 51 and the upper insulating film 53 is connected to the drain region 50c. A drain wiring 57 is provided on the upper insulating film 53, and the drain electrode 56 connects the drain region 50c and the drain wiring 57 to each other.

An interlayer dielectric 58 is provided on the upper insulating film 53, and the interlayer dielectric 58 covers the source wiring 55, the drain wiring 57, and the upper insulating film 53. An organic resin film 61 is provided on the interlayer dielectric 58, and a silicon nitride film 62 and a pixel electrode 63 are provided to overlap each other in this order on the organic resin film 61.

The pixel electrode 63 is formed in contact with the silicon nitride film 62. The organic resin film 61 and the silicon nitride film 62 are layers that insulate the source wiring 55 and the drain wiring 57 from the pixel electrode 63. The organic resin film 61 functions as a planarization layer for reflecting unevenness of the thin film transistor 49 on the pixel electrode 63.

A through electrode 56d is provided in the drain electrode 56, and the through electrode 56d penetrates the organic resin film 61 and is connected to the pixel electrode 63. The pixel electrodes 63 are separated per pixel region 64. The first base material 44, the thin film transistor 49, the organic resin film 61, the silicon nitride film 62, the pixel electrode 63, and the like constitute the first substrate 42. This way, the first substrate 42 has the same structure as the semiconductor device 1 according to the first embodiment. Accordingly, the electrophoresis apparatus 41 includes the same semiconductor device as the semiconductor device 1 according to the first embodiment.

Partition walls 65 are provided on the silicon nitride film 62 and the organic resin film 61, and the pixel region 64 partitioned by the partition walls 65 is filled with an electrophoresis dispersion 66. The partition walls 65 are provided so as to partition the pixel regions 64. The electrophoresis dispersion 66 includes white charged particles 67 and black charged particles 68. The white charged particles 67 are positively charged, and the black charged particles 68 are negatively charged.

The second substrate 43 is disposed on the electrophoresis dispersion 66. The second substrate 43 includes a second base material 69. The second substrate 43 is a transparent glass plate. A transparent common electrode 70 is provided on the second base material 69, and a transparent encapsulation layer 71 that encapsulates the electrophoresis dispersion 66 is provided on the common electrode 70. The common electrode 70 is provided across the plural pixel regions 64. Accordingly, the common electrode 70 is opposite to the plural pixel electrodes 63.

In a case where the voltage of the common electrode 70 is lower than that of the pixel electrode 63, the black charged particles 68 are charged to a negative voltage. Therefore, the black charged particles 68 are attracted to the pixel electrode 63. The white charged particles 67 are charged to a positive voltage. Therefore, the white charged particles 67 are attracted to the common electrode 70. As a result, the black charged particles 68 aggregate on the first substrate 42, and the white charged particles 67 aggregate on the second substrate 43. In a case where the electrophoresis apparatus 41 is seen from the second substrate 43 side, the white charged particles 67 can be seen through the second substrate 43. Accordingly, the pixel region 64 displays whitely.

In a case where the voltage of the common electrode 70 is higher than that of the pixel electrode 63, the white charged particles 67 are attracted to the pixel electrode 63. The black charged particles 68 are attracted to the common electrode 70. As a result, the pixel region 64 displays blackly. This way, the thin film transistor 49 switches the voltage of the common electrode 70 with respect to the pixel electrode 63 so as to switch the display color per pixel region 64.

In the electrophoresis apparatus 41, the gate electrode 52 is a film formed of molybdenum, and the internal stress thereof is a tensile stress. In the insulating film 48, the nitrogen concentration in the first silicon oxide film 45 is 3E²⁰ atoms/CC to 9E²⁰ atoms/CC, and the nitrogen concentration in the second silicon oxide film 47 is in the vicinity of 3E²¹ atoms/CC to 4E²¹ atoms/CC. Therefore, the internal stress of the first silicon oxide film 45 is compressive.

Accordingly, during formation of the gate electrode film 32 that forms abase of the gate electrode 52, the internal stress of the gate electrode film 32 and the internal stress of the first silicon oxide film 45 are well-balanced. Therefore, the warpage of the first base material 44 is suppressed. As a result, in the manufacturing process, a transport device can stably hold the first base material 44. In the electrophoresis apparatus 41 as an electronic apparatus, even in a case where the gate electrode film 32 formed of molybdenum is formed, the warpage of the first base material 44 can be suppressed.

### Third Embodiment

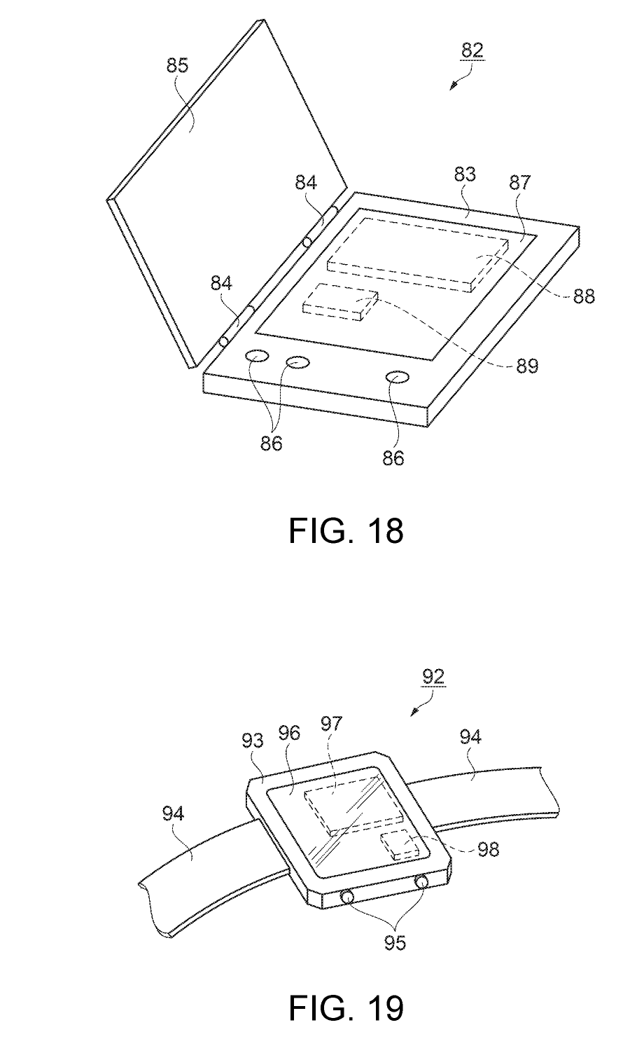

Next, an embodiment of an electronic apparatus on which the electrophoresis apparatus is mounted will be described using FIGS. 18 and 19. FIG. 18 is a schematic perspective view showing a structure of an electronic book, and FIG. 19 is a schematic perspective view showing a structure of a wristwatch. As shown in FIG. 18, an electronic book 82 as an electronic apparatus includes a case 83 having a plate shape. In the case 83, a lid portion 85 is provided through hinges 84. Further, on the case 83, operation buttons 86 and a display portion 87 are provided. An operator can operate the operation buttons 86 to operate the content that is displayed on the display portion 87.

In the case 83, a controller 88 and a signal driving portion 89 that drives the display portion 87 are provided. The controller 88 outputs display data to the signal driving portion 89, and also outputs a timing signal regarding the timing at which the display data is converted into a data signal. The signal driving portion 89 generates a data signal from the display data and outputs the data signal to the display portion 87. In addition, the controller 88 outputs a display control signal to the display portion 87 in synchronization with the data signal that is output from the signal driving portion 89. The display portion 87 includes a signal distribution circuit. The display portion 87 generates a signal required for electrophoretic display from the input display control signal and the input data signal. The display portion 87 performs display according to the display data output from the controller 88 to the display portion 87. The operation of the operator using the operation buttons 86 is timely encoded, is transmitted to the controller 88, and is reflected on the output signal of the controller 88.

This way, the electronic book 82 includes the display portion 87. As the display portion 87, the electrophoresis apparatus 41 is used. The electrophoresis apparatus 41 includes the semiconductor device 1 including the thin film transistor 49. As the gate electrode 52 of the thin film transistor 49, a film formed of molybdenum is used. Therefore, the internal stress of the gate electrode film 32 that forms a base of the gate electrode 52 is a tensile stress. In the insulating film 48, the nitrogen concentration in the first silicon oxide film 45 is 3E²⁰ atoms/CC to 9E²⁰ atoms/CC. As a result, the internal stress of the first silicon oxide film 45 is compressive.

During formation of the gate electrode film of the gate electrode 52, the internal stress of the gate electrode film and the internal stress of the first silicon oxide film 45 are well-balanced. Therefore, the warpage of the first base material 44 is suppressed. Accordingly, the display portion 87 suppresses the warpage of the first base material 44. As a result, in the electronic book 82, the warpage of the semiconductor device 1 and the display portion 87 can be suppressed. Thus, in the manufacturing process, a transport device can stably hold the first base material 44.

As shown in FIG. 19, a wristwatch 92 as an electronic apparatus includes a case 93 having a plate shape. The case 93 includes a band 94, and an operator wears the band 94 around a wrist such that the wristwatch 92 can be fixed to the wrist. On the case 93, operation buttons 95 and a display portion 96 are provided. The operator can operate the operation buttons 95 to operate the content that is displayed on the display portion 96.

In the case 93, a controller 97 that controls the wristwatch 92 and a signal driving portion 98 that drives the display portion 96 are provided. The controller 97 outputs display data and a necessary timing signal to the signal driving portion 98. The necessary timing signal may be a signal that is directly output from the controller 97 to the display portion 96. The signal driving portion 98 outputs a signal required for display to the display portion 96 such that the content corresponding to the display data can be displayed on the display portion 96.

The wristwatch 92 includes the display portion 96. As the display portion 96, the electrophoresis apparatus 41 is used. The electrophoresis apparatus 41 includes the semiconductor device 1 including the thin film transistor 49. As the gate electrode 52 of the thin film transistor 49, a film formed of molybdenum is used. Therefore, the internal stress of the gate electrode film 32 that forms a base of the gate electrode 52 is a tensile stress. In the insulating film 48, the nitrogen concentration in the first silicon oxide film 45 is 3E²⁰ atoms/CC to 9E²⁰ atoms/CC. As a result, the internal stress of the first silicon oxide film 45 is compressive.

During formation of the gate electrode film of the gate electrode 52, the internal stress of the gate electrode film and the internal stress of the first silicon oxide film 45 are well-balanced. Therefore, the warpage of the first base material 44 is suppressed. Accordingly, the display portion 96 suppresses the warpage of the first base material 44. As a result, in the wristwatch 92, the warpage of the semiconductor device 1 and the display portion 96 can be suppressed. Thus, in the manufacturing process, a transport device can stably hold the first base material 44.

The embodiments are not limited to the above-described configurations, and various modifications and improvements can be made by those skilled in the art within the technical scope of the invention. Modification examples are as follows.

### Modification Example 1

As described in the first embodiment, the step of forming the first silicon oxide film 4 of Step S1, the step of forming the silicon nitride film 5 of Step S2, the step of forming the second silicon oxide film 6 of Step S3, and the step of forming the silicon film of Step S4 can be continuously formed in the same chamber. On the other hand, the films in the respective steps may be formed in different chambers. The steps can be changed according to manufacturing facilities.

### Modification Example 2

In the first embodiment, as the substrate 3, a square glass plate is used. The external shape of the substrate 3 may be circular or polygonal. The shape can be changed according to a product to be manufactured.

The entire disclosure of Japanese Patent Application No. 2017-094469, filed May 11, 2017 is expressly incorporated by reference herein.

What is claimed is:

1. A semiconductor device comprising:
a substrate;
a thin film transistor; and
an insulating film that is provided between the substrate and the thin film transistor,
wherein the insulating film includes a first silicon oxide film, a silicon nitride film that is formed on the first silicon oxide film, and a second silicon oxide film that is formed on the silicon nitride film, and
a nitrogen concentration in the first silicon oxide film is lower than a nitrogen concentration in the second silicon oxide film.

2. The semiconductor device according to claim 1,
wherein the nitrogen concentration in the first silicon oxide film is 3E²⁰ atoms/CC to 9E²⁰ atoms/CC.

3. The semiconductor device according to claim 1,
wherein a gate electrode of the thin film transistor includes molybdenum.

4. An electronic apparatus comprising the semiconductor device according to claim 1.

5. An electronic apparatus comprising the semiconductor device according to claim 2.

6. An electronic apparatus comprising the semiconductor device according to claim 3.
